(19) United States
(12) Patent Application Publication
(10) Pub. No.: US 2007/0085086 A1
(43) Pub. Date: Apr. 19, 2007

(54) Organic light emitting device

(75) Inventors: Hiromichi GOHARA, Matsumoto City (JP); Koji Kawaguchi, Matsumoto City (JP); Toshio Hama, Yokosuka City (JP); Hiroki Sato, Yokosuka City (JP)

Correspondence Address: ROSSI, KIMMS & McDOWELL LLP., P.O. BOX 826, ASHBURN, VA, 20146-0826, US

(73) Assignee: Fuji Electric Holdings Co., Ltd., Kawasaki-ku (JP)

(21) Appl. No.: 11/548,735

(22) Filed: Oct. 12, 2006

(30) Foreign Application Priority Data
Oct. 18, 2005 (JP) 2005-302484

(51) Int. Cl. H01L 29/08; H01L 33/00

(52) U.S. Cl. 257/79; 257/40

(57) ABSTRACT

An organic light emitting device of high quality is disclosed that can be produced by a simple method and rarely causes color degradation due to current in the device. In one embodiment, the organic light emitting device comprises a substrate, a lower electrode disposed over the substrate, an organic light emitting layer disposed over the lower electrode and in electrical contact with the lower electrode, and an upper electrode disposed over the organic light emitting layer and in electrical contact with the organic light emitting layer. The upper electrode includes a first upper electrode element, a color conversion layer disposed on the first upper electrode element, and a second upper electrode element disposed on the color conversion layer and in electrical contact with the first upper electrode element.

### CROSS REFERENCE TO RELATED APPLICATIONS

This application is based on, and claims priority to, Japanese Patent Application No. 2005-302484, filed on Oct. 18, 2005, the contents of which are incorporated herein by reference.

### BACKGROUND OF THE INVENTION

A. Field of the Invention

The present invention relates to an organic light emitting device, in particular to an organic light emitting device that exhibits high precision and good visibility, and can be used in an organic electroluminescence (hereinafter referred to as organic EL) display apparatus widely applied for displaying in mobile terminals or measuring instruments in industries.

B. Description of the Related Art

A known example of light emitting devices used in display apparatuses is an organic EL device having laminated thin films of organic compounds. Organic EL devices are self light emitting device of a thin film and have excellent features of low driving voltage, high resolution, and wide view angle. They have been actively studied for practical applications.

An organic EL device has at least an organic light emitting layer between an anode and a cathode. The organic light emitting layer emits light by recombination of an electron and a positive hole that are generated by applying a voltage between an anode and a cathode. An organic EL device comprises, as necessary, a hole injection layer, a hole transport layer, an electron transport layer and an electron injection layer.

An organic EL device can emit light in blue, green or red color depending on the type of a dye added in an organic light emitting layer. A full color display can be achieved by arranging three sub-pixels of light emitting elements that emit three primary colors, in one pixel. However, the difference in characteristics between the light emitting elements for the three colors causes forming and driving processes for the sub-pixels to be rather complicated, which raises cost. Therefore efforts have been made to obtain the three primary colors from white color through color filters. Accordingly, an organic EL device emitting multi color or white light is demanded for use in a system using color filters.

Various techniques have been studied to obtain a white light emitting device. U.S. Pat. No. 6,285,039 discloses a method in which two or more colors of light emission are obtained from two or more light emitting layers including a mixed layer type light emitting layer containing two or more dopants. U.S. Pat. No. 5,683,823 discloses a method in which a red light emitting substance is homogeneously doped in a host material (blue-green light emitting substance) of a light emitting layer. Japanese Patent Unexamined Publication No. H6-207170 discloses a method in which a red color fluorescent compound is added into a lamination of a blue light emitting layer and a green light emitting layer. Japanese Patent Unexamined Publication No. H6-215874 discloses a method in which a fluorescent dye is added in a hole transport layer. Japanese Patent Unexamined Publication No. 2004-319471 and Japanese Patent Unexamined Publication No. H10-22073 each propose a method in which a part of blue green color light emitted from a light emitting layer is converted to red color, which in turn is mixed with transmitted part of blue green light, to obtain white light. Japanese Patent Unexamined Publication No. 2005-056855 and Japanese Patent Unexamined Publication No. 2002-231452 each propose a method in which blue color light obtained from a light emitting layer is converted to another color light by a fluorescent conversion layer disposed between an anode and a substrate or between an anode and a cathode.

To obtain white light emission in the methods mentioned above, it is necessary to laminate two or more light emitting layers and dope a plurality of different fluorescent dyes, or to add two or more types of fluorescent dyes even in the case of a single light emitting layer. The former needs an increased number of layers. The latter needs to control a low-energy red color fluorescent dye at a very low concentration for obtaining optimal white light emission. The production processes in the both cases involve problems of a complicated layer structure or difficulty of the control. In addition, in the white light emitting device produced by these methods, the organic light emitting device may degrade due to electric current applied to the device, and the color from the device can change.

When the white light emission is obtained using a color conversion layer, the problem of color change due to current in the device does not exist. However, in a color conversion layer, which is normally formed by photolithography, the moisture may not be thoroughly removed because the fluorescent dye in the color conversion layer has poor heat resistance. The moisture remained in the color conversion layer invades into the pixel region and generates non-light-emitting region (dark area: DA), degrading display quality.

The present invention is directed to overcoming or at least reducing the effects of one or more of the problems set forth above.

### SUMMARY OF THE INVENTION

In light of the above-described problems in the prior art, an object of the present invention is to provide an organic light emitting device of high quality that can be produced by a simple method and that rarely causes color degradation due to current in the device.

According to an aspect of the present invention, an organic light emitting device is provided that comprises a substrate; a lower electrode disposed over the substrate; an organic light emitting layer disposed over the lower electrode and in electrical contact with the lower electrode; and an upper electrode disposed over the organic light emitting layer and in electrical contact with the organic light emitting layer; wherein the upper electrode includes a first upper electrode element, a color conversion layer disposed on the first upper electrode element, and a second upper electrode element disposed on the color conversion layer and in electrical contact with the first upper electrode element.

According to another aspect of the present invention, an organic light emitting device is provided that comprises a substrate; a lower electrode disposed over the substrate; an organic light emitting layer disposed over the lower electrode and in electrical contact with the lower electrode; and an upper electrode disposed over the organic light emitting layer and in electrical contact with the organic light emitting layer; wherein the lower electrode includes a first lower electrode element, a color conversion layer disposed on the first lower electrode element, and a second lower electrode element disposed on the color conversion layer and in electrical contact with the first lower electrode element.

According to another aspect of the present invention, an organic EL panel is provided that is an organic EL panel for organic EL display displaying information by individually driving a plurality of pixels, wherein each of the pixels has a plurality of sub-pixels of different types, at least one type of the sub-pixels comprising the organic light emitting device as described above, and a color adjustment layer disposed in an area substantially overlapping with the organic light emitting device.

According to another aspect of the present invention, an organic EL display device is provided that comprises the organic light emitting device as described above, or the organic EL panel as described above.

According to another aspect of the present invention, a method of producing an organic light emitting device is provided, the method comprising steps of preparing a substrate; providing a lower electrode over the substrate; providing an organic light emitting layer disposed over the lower electrode and in electrical contact with the lower electrode; and providing an upper electrode disposed over the organic light emitting layer and in electrical contact with the organic light emitting layer; wherein the step of providing the upper electrode includes a step of providing a first upper electrode element, a step of providing a color conversion layer on the first upper electrode element, and a step of providing a second upper electrode element disposed on the color conversion layer and in electrical contact with the first upper electrode element.

According to another aspect of the present invention, a method of producing an organic light emitting device is provided, the method comprising steps of preparing a substrate; providing a lower electrode over the substrate; providing an organic light emitting layer disposed over the lower electrode and in electrical contact with the lower electrode; and providing an upper electrode disposed over the organic light emitting layer and in electrical contact with the organic light emitting layer; wherein the step of providing the lower electrode includes a step of providing a first lower electrode element, a step of providing a color conversion layer on the first lower electrode element, and a step of providing a second lower electrode element disposed on the color conversion layer and in electrical contact with the first lower electrode element.

As described in detail in the following, the present invention provides an organic light emitting device of high quality that can be produced by a simple method and rarely causes color degradation due to current in the device.

### BRIEF DESCRIPTION OF THE DRAWINGS

The foregoing advantages and features of the invention will become apparent upon reference to the following detailed description and the accompanying drawings, of which:

FIG. 1 is a sectional view of an example of an organic light emitting device of a first aspect of embodiment according to the invention;

FIG. 2 is a sectional view of an example of an organic light emitting device of a second aspect of embodiment according to the invention;

FIG. 3 is a schematic plan view of an organic EL panel according to the invention;

FIG. 4 is a sectional view of an organic EL display of Example 1;

FIG. 5 is a sectional view of an organic EL display of Example 2;

FIG. 6 is a sectional view of an organic EL display of Comparative Example 1;

FIG. 7 is a sectional view of an organic EL display of Comparative Example 2;

FIG. 8 is a sectional view of an organic light emitting device of Example 3; and

FIG. 9 is a sectional view of an organic light emitting device of Comparative Example 3.

### DETAILED DESCRIPTION OF SPECIFIC EMBODIMENTS

Now, some preferred embodiments according to the invention will be described in detail in the following with reference to the accompanying drawings. The present invention, however, shall not be limited to the preferred embodiments.

As described previously, an aspect of the present invention provides an organic light emitting device comprising a substrate, a lower electrode disposed over the substrate, an organic light emitting layer disposed over the lower electrode and in electrical contact with the lower electrode, and an upper electrode disposed over the organic light emitting layer and in electrical contact with the organic light emitting layer. An organic light emitting device of the invention can be applied to either a bottom emission type (light from an organic light emitting layer is used through a substrate) or top emission type (light from an organic light emitting layer is used not through a substrate).

An organic light emitting device of the invention has a substrate, as described previously. The substrate preferably withstands the conditions for solvent, temperature, etc., in the process to form a lower electrode, an organic light emitting layer, an upper electrode, and other members disposed on the substrate. The substrate preferably exhibits good dimensional stability. In the case of an organic light emitting device of a bottom emission type, the substrate is preferably transparent. The transparent substrate is preferably transparent to the light that is obtained from the organic light emitting layer and the light that is converted by a color conversion layer, and particularly it is desired to be transparent to visible light (wavelength of 400 to 700 nm). The specific material for the transparent substrate can be selected from glass, and resins such as poly(ethylene terephthalate) and poly(methyl methacrylate). Exemplary materials for a transparent substrate are borosilicate glass or soda-lime glass. In the case of an organic light emitting device of a top emission type, a substrate material can be selected from any appropriate materials. Thickness of the substrate can be 1.1 mm, for example.

An organic light emitting device of the invention comprises a lower electrode disposed over the substrate, as described previously. The wording “disposed over something” in this specification is intended to mean that something is disposed on the side of an organic light emitting layer with respect to a substrate. Thus, “a lower electrode is disposed over the substrate” includes the case where a lower electrode is disposed over the substrate intercalating, for example, a color filter layer between the lower electrode and the substrate, as well as the case where the lower electrode is disposed directly on the substrate. The meaning of this wording is applied to other component members. Material for the lower electrode will be described later.

An organic light emitting device of the invention comprises an organic light emitting layer disposed over the lower electrode and in electrical contact with the lower electrode, as described previously. The organic light emitting layer emits light by recombination of an electron and a positive hole that are generated by applying a voltage between an anode and a cathode, as described earlier. An organic light emitting device can further include a hole injection layer, a hole transport layer, an electron transport layer, and an electron injection layer, as necessary. To improve electron injection efficiency, an organic light emitting device preferably has at least an electron injection layer. Specifically, an organic light emitting device can have the above-mentioned layers in the following sequence. In the organic light emitting device having the layer structures (1) through (6) below, an organic light emitting layer or a hole injection layer is electrically connected to an anode, and an organic light emitting layer, an electron transport layer, or an electron injection layer is electrically connected to a cathode.

(1) Organic light emitting layer

(2) Hole injection layer/Organic light emitting layer

(3) Organic light emitting layer/Electron transport layer

(4) Hole injection layer/Organic light emitting layer/Electron transport layer

(5) Hole injection layer/Hole transport layer/Organic light emitting layer/Electron transport layer

(6) Hole injection layer/Hole transport layer/Organic light emitting layer/Electron transport layer/Electron injection layer

Each of the above mentioned layers can be composed of known materials. To obtain emission of blue to blue-green color light, the material of an organic light emitting layer can be selected from fluorescent brightening agents such as benzothiazole, benzoimidazole, and benzoxazole, and metal chelate oxonium compounds, styryl benzene compounds, and aromatic dimethylidine compounds. Examples of hole injection layer material include phthalocyanine compounds such as copper phthalocyanine, and triphenyl amine derivatives such as m-MTDATA. Examples of hole transport layer material include biphenyl amine derivatives such as TPD and α-NPD. Examples of electron transport layer material include oxadiazole derivatives such as PBD, and triazole derivatives, and triazine derivatives. Examples of electron injection layer material include quinolinol complex of aluminum, alkali metals, alkaline earth metals, and alloys containing these metals, and alkali metal fluorides.

Thicknesses of a hole injection layer, a hole transport layer, an organic light emitting layer, an electron transport layer, and an electron injection layer can be, for example, 100 nm, 20 nm, 30 nm, 30 nm, and 1 nm, respectively. The hole injection layer, the hole transport layer, the organic light emitting layer, the electron transport layer, and the electron injection layer can be formed by a known method, for example, an evaporation method.

An organic light emitting device of the invention comprises an upper electrode disposed over the organic light emitting layer and in contact with the organic light emitting layer. Material for the upper electrode will be described later.

In an organic light emitting device of the invention, at least one of the upper electrode and the lower electrode comprises a first electrode element, a color conversion layer disposed on the first electrode element, and a second electrode element disposed on the color conversion layer and in electrical contact with the first electrode element.

Specifically, in an organic light emitting device of the first aspect of embodiment according to the invention, the upper electrode comprises a first upper electrode element, a color conversion layer disposed on the first upper electrode element, and a second upper electrode element disposed on the color conversion layer and in electrical contact with the first upper electrode element. An organic light emitting device of the first aspect of embodiment according to the invention can be either a bottom emission type or a top emission type, as described later.

More specifically, in the case of a bottom emission type organic light emitting device, the first upper electrode element is preferably transparent to visible light, and the second upper electrode element is preferably reflective to visible light. In the case of a top emission type organic light emitting device, both of the first upper electrode element and the second upper electrode element are preferably transparent to visible light. The transparent first upper electrode element and reflective second upper electrode element make a bottom emission type organic light emitting device, which utilizes light from an organic light emitting layer transmitting through the substrate. On the other hand, transparent first and second upper electrode elements make a top emission type organic light emitting device, which utilizes light from the organic light emitting layer without transmitting through the substrate but from the side opposite to the substrate.

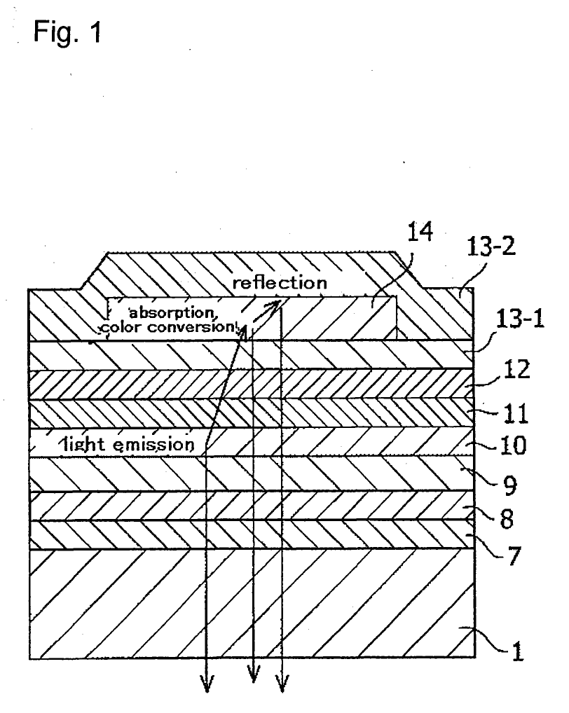

FIG. 1 is a sectional view of an example of an organic light emitting device of a first embodiment according to the invention. The organic light emitting device of FIG. 1 is a bottom emission type. Referring to FIG. 1, the organic light emitting device comprises a transparent substrate 1, a lower electrode (anode) 7, a hole injection layer 8, a hole transport layer 9, an organic light emitting layer 10, an electron transport layer 11, an electron injection layer 12, a first upper electrode element (cathode) 13-1, a color conversion layer 14, and a second upper electrode element (cathode) 13-2.

In an organic light emitting device of a second embodiment according to the invention, the lower electrode comprises a first lower electrode element, a color conversion layer disposed on the first lower electrode element, and a second lower electrode element disposed on the color conversion layer and in electrical contact with the first lower electrode element. The organic light emitting device of a second aspect of embodiment according to the invention, as of the first aspect of embodiment, can be either a bottom emission type or a top emission type.

In the case of a bottom emission type organic light emitting device, the first lower electrode element and the second lower electrode element are preferably transparent to visible light. In the case of a top emission type organic light emitting device, the first lower electrode element is preferably reflective to visible light and the second lower electrode element is preferably transparent to visible light.

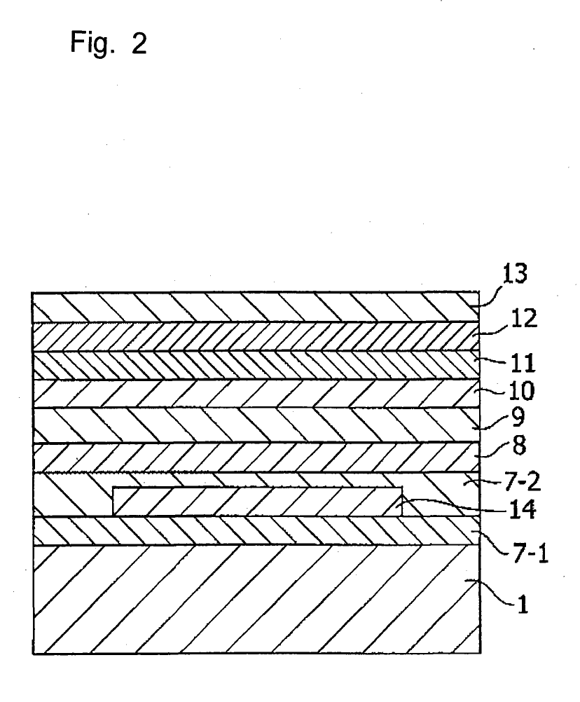

FIG. 2 is a sectional view of an example of an organic light emitting device of a second embodiment according to the invention. The organic light emitting device of FIG. 2 is a bottom emission type. Referring to FIG. 2, the organic light emitting device comprises transparent substrate 1, first lower electrode element (anode) 7-1, color conversion layer 14, second lower electrode element (anode) 7-2, hole injection layer 8, hole transport layer 9, organic light emitting layer 10, electron transport layer 11, electron injection layer 12, and upper electrode (cathode) 13.

The first and second electrode elements are in electrical contact with each other. An electrode that is transparent to visible light generally has a lower conductivity (for example, more than one order of magnitude lower) than a normal electrode. In the device according to the present invention, the first electrode element and the second electrode element in electrical contact with each other can be used as an electron injection electrode and an electron conduction electrode, respectively, in order to reduce wiring resistance that may be increased by using transparent electrodes. In the case of passive driving, electric current flows more in a scanning side electrode (generally upper electrode) than in a data side electrode. Accordingly, resistance of the scanning side electrode is desirably reduced for reduction of power consumption of a device.

In an embodiment having an upper electrode that comprises a first upper electrode element and a second upper electrode element, a color conversion layer is improved in resistance to environmental conditions, such as moisture and oxygen, by covering the color conversion layer with the first upper electrode element and the second upper electrode element. In an embodiment having a lower electrode that comprises a first lower electrode element and a second lower electrode element, a structure having color filters and a protective layer provided between a color conversion layer and a substrate by photolithography can eliminate the adverse effect of moisture from these lower layers by provision of the first lower electrode element, as described in detail later.

The first electrode element and the second electrode element are made in contact with each other and at the same electrical potential. As a result, a color conversion layer disposed within the device does not alter the hole and electron flow with respect to the organic light emitting layer. So, the influence of the color conversion layer on the electrical performance of the device is avoided. If the color conversion layer is disposed between an upper electrode and a lower electrode, the color conversion layer must perform electron or hole transport ability. Therefore, materials that can be used are limited and technical difficulty increases.

The second electrode element is preferably disposed in an area substantially overlapping the first electrode element. The wording “overlapping area” means an area of overlap when the organic light emitting layer is seen from the direction perpendicular to the substrate. That is, the first electrode element and the second electrode element preferably overlap each other when the organic light emitting layer is seen from the direction perpendicular to the substrate.

The color conversion layer is so disposed in the area overlapping the first electrode element that the first electrode element and the second electrode element are in contact with each other. By disposing in this configuration, electrical contact between the first electrode element and the second electrode element are ensured even in the case the second electrode element is disposed in an area substantially overlapping the first electrode element. An area of the color conversion layer can be appropriately set to obtain desired white light emission. For example, the color conversion layers can have a circular shape with a diameter of 5 μm to 50 μm and can be arranged with a gap of 5 μm to 20 μm. These ranges do not result in visual unevenness. Because the first electrode element and the second electrode element are in electrical contact in the device according to the invention, injection of electrons or holes into the organic light emitting layer (or electron injection layer or the like) is made through planar contact from the first or second electrode element. Therefore, color conversion can be accomplished without impairing injection performance of electrons or holes in the device according to the present invention. Because a color conversion layer is disposed between a first electrode element and a second electrode element according to the invention, there is no problem of reflection at the glass interface and the light from an organic light emitting layer is effectively utilized.

Known materials can be used for an electrode element that is transparent to visible light and an electrode element that is reflective to visible light. If a transparent electrode element is used in a lower electrode, an amorphous film is preferable because of good flatness. Specifically, materials for a transparent electrode element include oxides of at least one metal selected from the group consisting of In, Sn, Zn, and Al. If the transparent electrode element is in contact with an electron injection layer or an electron transport layer, an extremely thin film of metal can also be used for the transparent electrode element to achieve good electron injection performance. Such a material for the transparent electrode element of a thin metallic film can be selected from the group consisting of aluminum, an Al—Li alloy, magnesium, and an Mg—Ag alloy. A reflective electrode element preferably includes a metal selected from the group consisting of Al, Ag, Ni, Cr, Mo, and W. A material for an electrode element, for example, aluminum, can be used as a reflective electrode element by setting the thickness at more than 100 nm, while optical transparency can be increased by setting the thickness very small. In a device according to the present invention, an electrode element material of aluminum for example, can exhibit sufficient transparency by setting the thickness at about 50 nm or thinner.

The color conversion layer preferably contains a fluorescent dye, a phosphorescent dye, or both. The color conversion layer preferably absorbs light from the organic light emitting layer and emits light having a wavelength different from that of the light from the organic light emitting layer. A wavelength of light possibly absorbed by the color conversion layer and a wavelength of light possibly emitted by the color conversion layer suitably is selected corresponding to the wavelength possibly emitted by the organic light emitting layer. It is particularly desirable for the organic light emitting layer to emit light in the wavelength range of 400 to 500 nm (blue to blue-green color), and for the color conversion layer to emit light in the wavelength range of at least 580 nm (red color).

Specific examples of material for a color conversion layer include 4-(dicyanomethylene)-2-methyl-6-(p-dimethylaminostyryl)-4H-pyran (DCM), 4,4-difluoro-1,3,5,7-tetraphenyl-4-bora-3a,4a-diaza-s-indacene, propane dinitrile, and Nile Red. 2,5-bis-(5-tert-butyl-2-benzoxazolyl)-thiophene, and biphenyl. The color conversion layer can be composed of a plurality of materials. For example, a color conversion layer can be formed by adding the above-mentioned material to a host material selected from tris(8-hydroxyquinoline) aluminum complex (Alq₃), 4,4′-bis-(2,2′-diphenyl vinyl), 2,5-bis-(5-tert-butyl-2-benzoxazolyl)-thiophene, and biphenyl. Because voltage is not applied to a color conversion layer in the present invention, material for the color conversion layer can be selected from electrically insulative materials as well as electrically conductive materials.

The color conversion layer preferably has an absorbance of at least 1.0 (a light absorption coefficient of at least 90%) at an absorption peak wavelength for the light from the organic light emitting layer. By this measure, the intensity of the light from the color conversion layer (red color, for example) can be increased. The absorbance can be measured, for example, by irradiating a sample with a monochromatic light and measure the quantity of transmitted light.

In the case without sandwiching a color conversion layer, thickness of the electrode can be 100 nm, for example. Thicknesses of a first electrode element and a second electrode element sandwiching a color conversion layer can be set in the following way, in an example of color conversion layer thickness of 100 nm. In the case of a bottom emission type with a color conversion layer sandwiched between upper electrode elements, the thicknesses of the first upper electrode element (transparent) can be in the range of 20 to 50 nm, and the thickness of the second upper electrode element (reflective) can be in the range of 100 to 200 nm. In the case of a top emission type with a color conversion layer sandwiched between upper electrode elements, the thickness of the first upper electrode (transparent) can be in the range of 100 to 150 nm, and the thickness of the second upper electrode element (transparent) can be in the range of 100 to 200 nm. In the case of bottom emission type with a color conversion layer sandwiched between lower electrode elements, the thickness of the first lower electrode element (transparent) can be in the range of 100 to 200 nm, and the thickness of the second lower electrode element (transparent) can be in the range of 100 to 150 nm. In the case of top emission type with a color conversion layer sandwiched between lower electrode elements, the thickness of the first lower electrode element (reflective) can be in the range of 100 to 200 nm, and the thickness of the second lower electrode element (transparent) can be in the range of 20 to 50 nm. An electrode element disposed between the color conversion layer and the organic light emitting layer is transparent to visible light and preferably exhibits good carrier injection performance. The carrier injection performance is determined depending on the material used. An electrode element at an outside of the device preferably exhibits good reflectivity or transparency depending on the device construction, and a low wiring resistance as well. When the transparency and the wiring resistance are controlled by film thickness in the case of outer transparent electrode element, these properties are in a trade-off relationship, and the thickness must be determined considering balance between the properties.

Thickness of the color conversion layer can be appropriately set to obtain desired white light emission. The thickness of the color conversion layer is preferably in the range of 100 to 200 nm since absorbance can be adequately optimized in this range.

Either a lower electrode or upper electrode is possibly an anode or a cathode. Oxide materials used for a transparent electrode disposed on the side of light extraction, having a large work function and advantageous for hole injection performance, are generally used for an anode. Therefore, a bottom emission type device tends to have an anode as the lower electrode and a cathode as the upper electrode, while a top emission type device is apt to have a cathode as the lower electrode and an anode as the upper electrode.

The electrode can be formed by a known technique. Examples of methods for forming an electrode include a sputtering method such as DC sputtering and an evaporation method. A patterning method in the process of forming an electrode can be a lift-off technique or a commonly employed photolithography method.

A color conversion layer can be formed by a known method. Examples of methods for forming a color conversion layer include a vacuum evaporation method, an inkjet method, and a spin coating method. A color conversion layer preferably is disposed in an area overlapping with the first electrode element in the condition that the first electrode element and a second electrode element are in contact with each other. Consequently, the color conversion layer preferably is formed such that a part of the first electrode element remains exposed. Specifically, the color conversion layer preferably is formed using a mask that covers outside of the area overlapping the first electrode element and a part of the area overlapping the first electrode element.

In the conventional procedure which forms a color filter, a color conversion layer, a planarizing layer, a passivation layer, a lower electrode (an anode), an organic light emitting layer, and an upper electrode (a cathode) on a substrate in this order, the treatment temperature in the processes of forming the planarizing layer and the passivation layer is limited, for example, to 200° C., to avoid deterioration of the material for the color conversion layer. In contrast, a color conversion layer is formed within an electrode in the invention and after forming the planarizing layer and the passivation layer. Consequently, the treatment temperature in the process of forming the planarizing layer and the passivation layer in the invention can be higher than that conventionally used, allowing thorough elimination of moisture contained in the color filter and other layers. In addition, a planarizing layer and a passivation layer exhibiting better quality can be obtained. As a result, the defects of dark area and dark spots, which can be considered to occur due to moisture, are prevented in the device of the invention.

In the conventional procedure which forms a color filter, a color conversion layer, a planarizing layer, a passivation layer, a lower electrode (an anode), an organic light emitting layer, and an upper electrode (a cathode) on a substrate in this order, the color conversion layer is formed by means of photolithography. If a color conversion layer is formed by means of evaporation, each sub-pixel needs to be deposited using a mask, requiring high precision aligning. In contrast, the color conversion layer in the invention is disposed within an electrode and used as a complementary color layer that complements the light from an organic light emitting layer, so a mask is not needed for depositing the color conversion layer and the color conversion layer can be formed by means of evaporation without considering the problem of precision.

An organic light emitting device preferably comprises a protective layer for a color conversion layer disposed between a first electrode element and a color conversion layer or between a color conversion layer and a second electrode element. More preferably, two protective layers for a color conversion layer are provided between the first electrode element and the color conversion layer and between the second electrode element and the color conversion layer, and the color conversion layer is sealed with the protective layers for the color conversion layer. Examples of materials for the protective layer for a color conversion layer include MgF₂ and CaF₂. These materials are highly transparent over a wide wavelength range from vacuum ultraviolet to infrared region up to 10 μm. The materials are chemically and physically stable, and exhibit good ability to withstand moisture, chemicals, and heat. Thickness of the protective layer for a color conversion layer can be in the range of 100 to 200 nm. The protective layer for a color conversion layer can be formed by a known method such as an evaporation method.

An organic light emitting device of the invention preferably further comprises an encapsulation structure disposed over the upper electrode. The encapsulation structure can be any known structure, for example, a sealing glass bonded with a UV-curing adhesive in a dry nitrogen atmosphere. An encapsulation structure can be a SiN layer formed on an upper electrode. The SiN layer is used as a passivation film.

In an organic light emitting device that is a bottom emission type and has a color conversion layer between first and second upper electrode elements (cathode), as shown in FIG. 1, an organic light emitting layer emits light (blue or blue-green color light, for example) in all directions upon application of a voltage between a lower electrode (anode) and an upper electrode (cathode). A part of the light from the organic light emitting layer transmits through a first upper electrode element (cathode) and reaches the color conversion layer, where the light is absorbed in the color conversion layer and is converted to light having a wavelength region (for example, red color light) different from the light from the organic light emitting layer. The converted light is also emitted in all directions. Consequently, an organic light emitting device according to the present invention can utilize the light converted by the color conversion layer (red color light, for example) as well as the light emitted from the organic light emitting layer (blue or blue-green color light) to obtain light with a wide wavelength range. If an organic light emitting layer emits blue color light or blue-green color light, the organic light emitting device also obtains red color light from the color conversion layer, thus, the organic light emitting device as a whole can emit white light. A second upper electrode element (cathode), when made reflective, allows the color-converted light to be more effectively utilized. A similar effect can be obtained in an organic light emitting device that is a top emission type and a device that has a color conversion layer between first and second lower electrode elements (anode).

In a conventional organic light emitting device for obtaining white light by laminating a red light emitting layer and a blue light emitting layer, the color of the emitted light and the electrical characteristics change depending on the dopant concentration and the film thickness of each light emitting layer. In a device having a color conversion layer simply disposed in a part of the device where electrons and holes flow, the color conversion layer must give transport ability for electrons and holes, which imposes a restraint on the employed material used, and causes technological difficulties. In contrast, in a device according to the present invention, only the organic light emitting layer emits light (blue to blue-green light, for example) by EL that demands electric energy. Other color light (red color, for example) that is deficient in the light from the organic light emitting layer is given by photoluminescence (PL) absorbing a part of the light from the organic light emitting layer. Therefore, an organic light emitting layer need not contain various dyes, and stable light emission can be achieved without degrading light emission efficiency due to energy trapping by the dyes.

In a conventional method as described above, a light emitting layer consisting of two layers has been devised to obtain white light, which involves a problem of dopant density control. In the device according to the present invention, in contrast, a light emitting layer only needs a single light emission owing to the use of a color conversion layer, so a complicated design is not required. Therefore, an organic light emitting device of the invention can be produced by a relatively simple procedure.

Another aspect of the present invention provides an organic EL panel for an organic EL display that individually drives a plurality of pixels and displays information. Each pixel of an organic EL panel of the invention consists of plural types of sub-pixels (for example, blue color, green color, and red color sub-pixels). At least one type of the sub-pixels comprises the organic light emitting device as described above and a color adjustment layer disposed in an area substantially overlapping with the organic light emitting device. Preferably, the upper electrode is striped, the lower electrode is striped, and the upper electrodes and the lower electrodes are disposed in a matrix configuration. An organic EL panel of the invention can employ both bottom emission type and top emission type of organic light emitting devices.

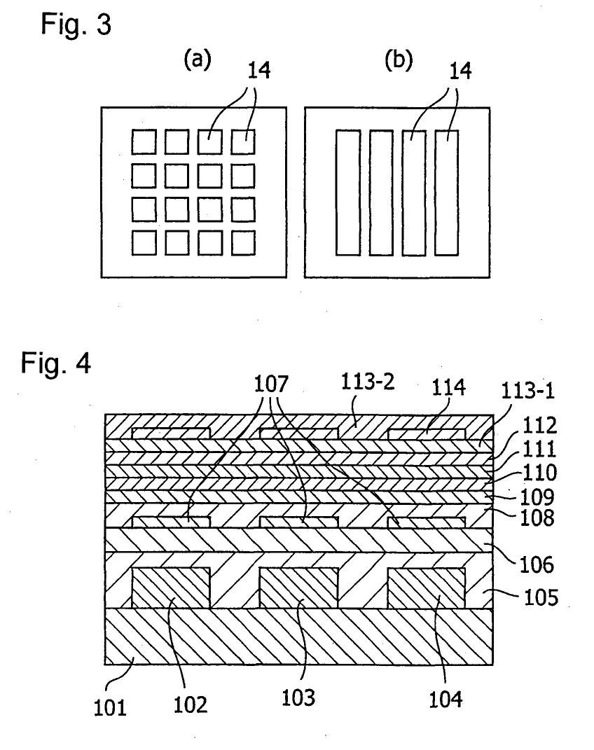

An organic EL panel of the invention comprises an organic light emitting device(s) of the invention, as described above. The organic light emitting layer is preferably disposed in an area where an upper electrode and a lower electrode are overlapping. A type of sub-pixel that can use the light from an organic light emitting layer without color conversion can use an organic light emitting device lacking a color conversion layer. FIG. 3 is a schematic plan view of an organic EL panel according to the present invention. In FIG. 3, elements other than color conversion layers are omitted for simplicity. Color conversion layers can be arranged in a pattern consisting of units of circular, square, or rectangular shape with a predetermined gap. A color conversion layer can be provided corresponding to an individual sub-pixel, or in one-piece for a plurality of sub-pixels. In one aspect of embodiment, a color conversion layer has a circular or a square shape (as shown in FIG. 3(a)) and is disposed in an area where the upper electrode and the lower electrode are overlapping. In the case of a color conversion layer of a circular shape, in particular, the electrical contact area between the first electrode element and the second electrode element is large and good performance is achieved in electron injection from the electrode to the organic light emitting layer. In another embodiment, a color conversion layer has a rectangular shape as shown in FIG. 3(b) and preferably is disposed in an area where the upper electrode or the lower electrode overlap the color conversion layer.

An organic EL panel of the present invention comprises a color adjustment layer disposed in an area substantially overlapping the organic light emitting layer. The color adjustment layer here means a color filter layer that cuts off a part of the wavelength range of the light from the organic light emitting layer, a color conversion layer that absorbs the light from the organic light emitting layer and emits light with a wavelength different from the wavelength of the light of the organic light emitting layer, or a layer that performs both functions. Since stable white light can be obtained by a structure having a color conversion layer between a first electrode element and a second electrode element according to the present invention, an organic EL panel of the invention preferably has a color filter layer that cuts off a part of the wavelength range of the light. In the case of employing a bottom emission type organic light emitting device, the color adjustment layer is disposed on the side of substrate with respect to the organic light emitting layer. In the case of employing a top emission type organic light emitting device, the color adjustment layer is disposed on the side opposite to the substrate with respect to the organic light emitting layer. An organic EL panel of the invention comprises a color adjustment layer to obtain desired color light at each sub-pixel. Specifically, an organic EL panel preferably has a blue color filter layer, a green color filter layer, and a red color filter layer to obtain blue color, green color, and red color light. Material for the color adjustment layer can be selected from known materials. Thickness of the color adjustment layer can be in the range of 0.5 to 2 μm, for example, 1 μm. The color adjustment layer can be formed by a known method. The color adjustment layer can be formed, for example, by applying an appropriate material by spin coating, and then patterning by photolithography.

An organic EL display according to the present invention, in the case of employing an organic light emitting device of a bottom emission type, preferably comprises a planarizing layer disposed between the lower electrode and the color adjustment layer. Material for the planarizing layer can be selected from known materials. Thickness of the planarizing layer can be 1 to 2 μm, for example, 1 μm, measured from the glass substrate surface. The planarizing layer can be formed by a known method. The planarizing layer can be formed, for example, by applying a UV-curing resin by spin coating, and curing by illumination of UV light.

An organic EL display according to the present invention, in the case of employing an organic light emitting device of a bottom emission type, preferably comprises a passivation layer disposed between the lower electrode and the planarizing layer. Material of the passivation layer can be selected from known materials including oxide films, nitride films, and oxide-nitride films of silicon, aluminum, or the like. Thickness of the passivation layer can be 300 nm, for example. The passivation layer can be formed by a known method for example, an RF sputtering method.

### EXAMPLES

Some specific examples of embodiment according to the present invention will be described with reference to the accompanying drawings. The invention, however, shall not be limited to the examples.

Organic EL displays of Examples 1 and 2, and Comparative Examples 1 and 2 were produced having pixels of 60×80×RGB and a pixel pitch of 0.33 mm. Organic light emitting devices for white color light of Example 3 and Comparative Example 3 were produced having a shape of 2 mm square.

### Example 1

### Bottom Emission Type; a Color Conversion Layer Between Upper Electrode Elements (Cathode)

FIG. 4 is a sectional view of the organic EL display of Example 1. The organic EL display of Example 1 is a bottom emission type and employs a color conversion scheme. As shown in FIG. 4, the organic EL display of Example 1 comprises transparent substrate 101, blue color filter layer 102, green color filter layer 103, red color filter layer 104, planarizing layer 105 of a polymer, passivation layer 106, lower electrode (anode) 107, hole injection layer 108, hole transport layer 109, organic light emitting layer 110, electron transport layer 111, electron injection layer 112, first upper electrode element (cathode) 113-1, color conversion layer 114, and second upper electrode element (cathode) 113-2.

Transparent substrate 101 was made of corning glass (50×50×1.1 mm). Blue color filter layer 102 was formed on transparent substrate 101 as follows. The material of blue color filter layer 102 was Color Mosaic CB-7001, a product of Fuji Film Electronic Materials, Co., Ltd. This material was applied on transparent substrate 101 by a spin coating method, and patterning was conducted by a photolithography method. Thus, blue color filter layer 102 was formed with a line pattern of a line width of 0.1 mm, a pitch of 0.33 mm, and a film thickness of 1 μm.

Green color filter layer 103 was formed on transparent substrate 101 as follows. The material of green color filter layer 103 was Color Mosaic CG-7001, a product of Fuji Film Electronic Materials, Co., Ltd. This material was applied on transparent substrate 101 having the line pattern of blue color filter layer by a spin coating method, and patterning was conducted by a photolithography method. Thus, green color filter layer 103 was formed with a line pattern of a line width of 0.1 mm, a pitch of 0.33 mm, and a film thickness of 1 μm.

Red color filter layer 104 was formed on transparent substrate 101 as follows. The material of red color filter layer 104 was Color Mosaic CR-7001, a product of Fuji Film Electronic Materials, Co., Ltd. This material was applied on transparent substrate 101 having the line patterns of blue color filter layer and green color filter layer by a spin coating method, and patterning was conducted by a photolithography method. Thus, red color filter layer 104 was formed with a line pattern of a line width of 0.1 mm, a pitch of 0.33 mm, and a film thickness of 1 μm.

After that, planarizing layer 105 of a polymer was formed on those color adjustment layers (blue color filter layer 102, green color filter layer 103, and red color filter layer 104). The material of planarizing layer 105 of a polymer was a UV-curing resin (epoxy-modified acrylate). This material was applied on the color adjustment layer by a spin coating method and irradiated by a high pressure mercury lamp. Thus, planarizing layer 105 of a polymer was formed having a thickness of 1 μm from the glass substrate surface. In this process, the pattern of the color adjustment layer was not distorted and the top surface of the planarizing layer of polymer was flat. The processes of forming the blue color filter layer through the planarizing layer were carried out at a temperature in the range of 210° C. to 250° C.

Then, passivation layer 106 was formed on planarizing layer 105 of polymer as follows. Passivation layer 106 was formed by an RF sputtering method using a target of silicon and a sputtering gas of mixed gas of argon and oxygen, at room temperature. Thus, passivation layer 106 of SiOx film 300 nm thick was formed.

Then, lower electrode (anode) 107 was formed on passivation layer 106 as follows. First, indium zinc oxide (IZO), a material of the lower electrode, was deposited to a film thickness of 200 nm on the whole surface having the passivation layer by a DC magnetron sputtering method. Next, a stripe pattern of IZO was formed by a photolithography method using a photoresist to form the lower electrode. Specifically, a positive type photoresist, TFR-1150, a product of Tokyo Ohka Kogyo Co., Ltd., was applied on the whole surface, and then exposure and development were conducted to form a stripe pattern of a line width of 0.094 mm and a pitch of 0.11 mm, followed by post baking. Then, the excessive IZO was etched with oxalic acid using a mask of the photoresist pattern and the resist was removed with a solvent of NMP or the like. Thus, a stripe pattern of IZO was formed.

After that, transparent substrate 101 having lower electrode (anode) 107 formed thereon was installed in a resistance heating evaporation apparatus, and hole injection layer 108, hole transport layer 109, organic light emitting layer 110, electron transport layer 111, and electron injection layer 112 were sequentially deposited on lower electrode (anode) 107 without breaking the vacuum. The pressure in the vacuum chamber was reduced to 1×10⁻⁴ Pa in the deposition process. Hole injection layer 108 was formed by depositing copper phthalocyanine (CuPc) to a thickness of 100 nm. Hole transport layer 109 was formed by depositing 4,4′-bis[N-(1-naphthyl)-N-phenylamino]biphenyl (α-NPD) to a thickness of 20 nm. Organic light emitting layer 110 was formed by depositing 4,4′-bis(2,2′-diphenyl vinyl)biphenyl (DPVBi) to a thickness of 30 nm. Electron transport layer 111 was formed by depositing tris(8-hydroxyquinoline) aluminum complex (Alq₃) to a thickness of 20 nm. Electron injection layer 112 was formed by depositing LiF to a thickness of 1 nm. The processes of depositing hole injection layer 108, hole transport layer 109, organic light emitting layer 110, and electron transport layer 111 were conducted at a evaporation speed of 0.1 nm/s. The process of depositing electron injection layer 112 was conducted at an evaporation speed of 0.025 nm/s. This layer structure was principally for light emission in blue-green color. The following formulas are the structural formulas of the materials used for these layers.

Chemical Formula 1

Hole injection layer: copper phthalocyanine. 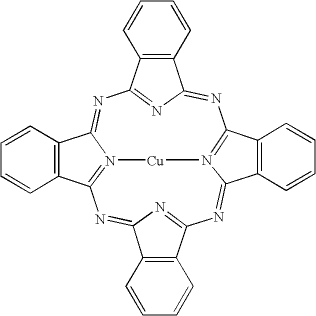
Chemical Formula 2

Hole transport layer: 4,4′-bis[N-(1-naphthyl)-N-phenylamino]biphenyl 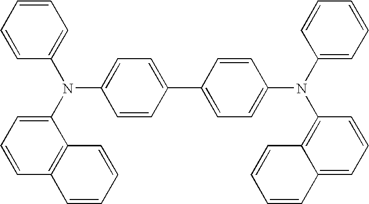
Chemical Formula 3

Organic light emitting layer: 4,4′-bis(2,2′-diphenyl vinyl)biphenyl 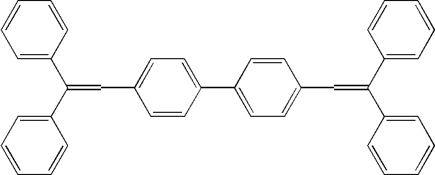
Chemical Formula 4

Electron transport layer: tris(8-hydroxyquinoline)aluminum complex

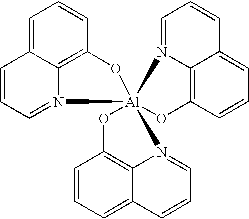

Then, first upper electrode element (cathode) 113-1, color conversion layer 114, and second upper electrode element (cathode) 113-2 were sequentially formed on electron injection layer 112 without breaking the vacuum. First upper electrode element (cathode) 113-1 was formed on electron injection layer 112 as follows. The deposition was conducted by means of an evaporation method using a mask to obtain a stripe pattern perpendicular to the lines of lower electrode (anode) 107 and having a line width of 0.3 mm and a pitch of 0.33 mm. The pressure in the evaporation process was 1×10⁻⁶ Torr and the evaporation speed was 0.5 nm/s. Thus, first upper electrode element (cathode) 113-1 of an aluminum layer 30 nm thick was formed.

Subsequently, color conversion layer 114 was formed on first upper electrode element (cathode) 113-1 without breaking the vacuum as follows. The deposition process was conducted by means of mask evaporation in an area where lower electrode (anode) 107 and first upper electrode element (cathode) 113-1 were overlapping, using a mask having an opening where at least a part of the first upper electrode element (cathode) 113-1 was exposed in an area overlapping lower electrode (anode) 107 and first upper electrode element (cathode) 113-1. More specifically, color conversion layers of circular shape with a diameter of 20 μm were arranged with a gap of 40 μm. (That was a pattern of color conversion layers arranged at lattice points on a planar rhombic lattice having one side of 60 μm.) The pressure in the vacuum chamber was reduced to 1×10⁻⁴ Pa in the deposition process. The material used for color conversion layer 114 was 4-(dicyanomethylene)-2-methyl-6-(p-dimethylamino styryl)-4H-pyran (DCM). Thus, color conversion layer 114 having a thickness of 100 nm was deposited.

Subsequently, second upper electrode element (cathode) 113-2 was formed on color conversion layer 114 without breaking the vacuum as follows. The deposition was conducted by means of an evaporation method using a mask to obtain a stripe pattern same as the lines on first upper electrode element (cathode) 113-1. Thus, second upper electrode element (cathode) 113-2 of aluminum layer 100 nm thick was formed.

The resulting organic light emitting device was sealed with a sealing glass (not shown in the figure) and a UV-curing adhesive under a dry nitrogen atmosphere in a globe box (both oxygen and moisture concentrations were not higher than 10 ppm).

### Example 2

### Bottom Emission Type; a Color Conversion Layer Between Lower Electrode Elements (Anode)

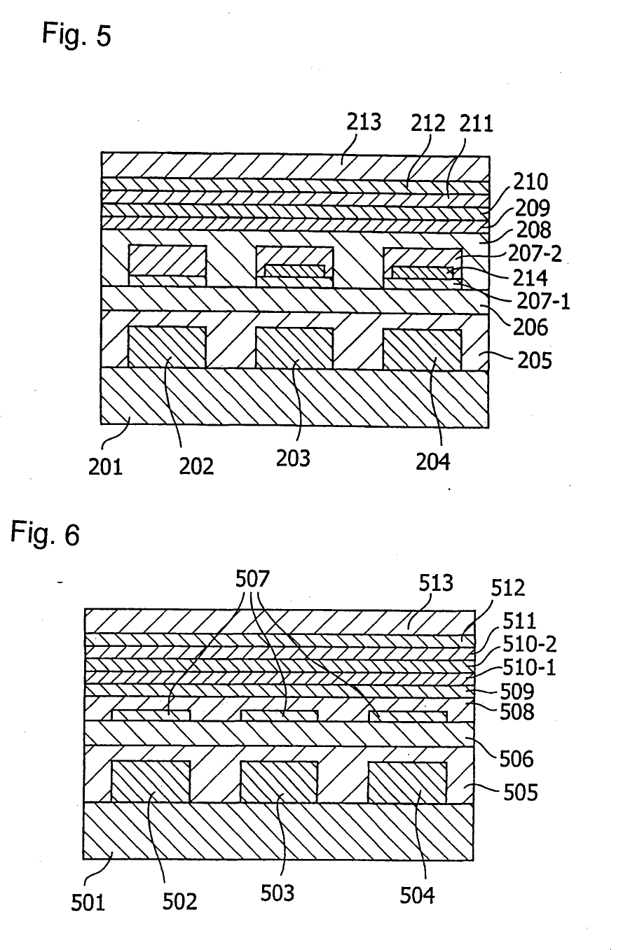

An organic EL display of Example 2 was produced in the same manner as in Example 1 except the points described in the following. FIG. 5 is a sectional view of the organic EL display of Example 2. The organic EL display of Example 2 comprises, as shown in FIG. 5, transparent substrate 201, blue color filter layer 202, green color filter layer 203, red color filter layer 204, planarizing layer 205 of polymer, passivation layer 206, first lower electrode element (anode) 207-1, color conversion layer 214, second lower electrode element (anode) 207-2, hole injection layer 208, hole transport layer 209, an organic light emitting layer 210, an electron transport layer 211, electron injection layer 212, and upper electrode (cathode) 213.

The organic EL display of Example 2 comprises first lower electrode element (anode) 207-1, color conversion layer 214, and second lower electrode element (anode) 207-2 formed on passivation layer 206. First, an IZO film 100 nm thick was deposited by means of a DC magnetron sputtering method to form a layer for first lower electrode elements. Then, the substrate was transferred into a evaporation chamber and a color conversion layer was formed by means of mask evaporation as in Example 1. Subsequently, an IZO film 100 nm thick was deposited by facing target sputtering method to form a layer for second lower electrode elements without breaking the vacuum. After that, the substrate was taken out of the deposition chamber and a patterning process was conducted on the IZO film together with the color conversion layer by a photolithography method as in the process for the lower electrode in Example 1. Dimensions of the pattern were the same as in Example 1.

After forming electron injection layer 212, upper electrode (cathode) 213 was formed on electron injection layer 212 without breaking the vacuum. The deposition of upper electrode (cathode) 213 was conducted by means of an evaporation method using a mask to obtain a stripe pattern perpendicular to the lines of the first and second lower electrode elements (anode) 207-1 and 207-2 and having a line width of 0.30 mm and a gap of 0.03 mm. Thus, upper electrode (cathode) 213 of aluminum 100 nm thick was formed.

### Comparative Example 1

### Bottom Emission Type

An organic EL display of Comparative Example 1 was produced in the same manner as in Example 1 except the points described in the following. FIG. 6 is a sectional view of an organic EL display of Comparative Example 1. The organic EL display of Comparative Example 1, as shown in FIG. 6, comprises transparent substrate 501, blue color filter layer 502, green color filter layer 503, red color filter layer 504, planarizing layer of polymer 505, passivation layer 506, lower electrode (anode) 507, hole injection layer 508, hole transport layer 509, blue light emitting layer 510-1, red light emitting layer 510-2, an electron transport layer 511, electron injection layer 512, and upper electrode (cathode) 513.

In the organic EL display of Comparative Example 1, blue light emitting layer 510-1 was formed as follows. The host substance for the blue light emitting layer was 4,4′-bis(2,2′-diphenylvinyl) biphenyl (DPVBi), and the guest substance was 4,4′-bis[2-{4-(N,N-diphenylamino)phenyl}vinyl]biphenyl (DPAVBi), and co-evaporation was conducted with a concentration ratio of the guest to the host of 2%. Thus, blue light emitting layer 510-1 having a thickness of 10 nm was formed.

Red light emitting layer 510-2 was formed as follows. The host for the red light emitting layer was DPVBi and the guest was 4-dicyanomethylene-2-methyl-6-p-dimethylamino styryl-4H-pyran (DCM), and co-evaporation was conducted with a concentration ratio of guest to host of 1%. Thus, red light emitting layer 510-2 having a thickness of 30 nm was formed.

Upper electrode (cathode) 513 was formed as follows. Similar to the case of the second upper electrode element (cathode) in Example 1, an aluminum layer 100 nm thick was formed as the upper electrode (cathode) by means of a mask evaporation method.

### Comparative Example 2

### Bottom Emission Type

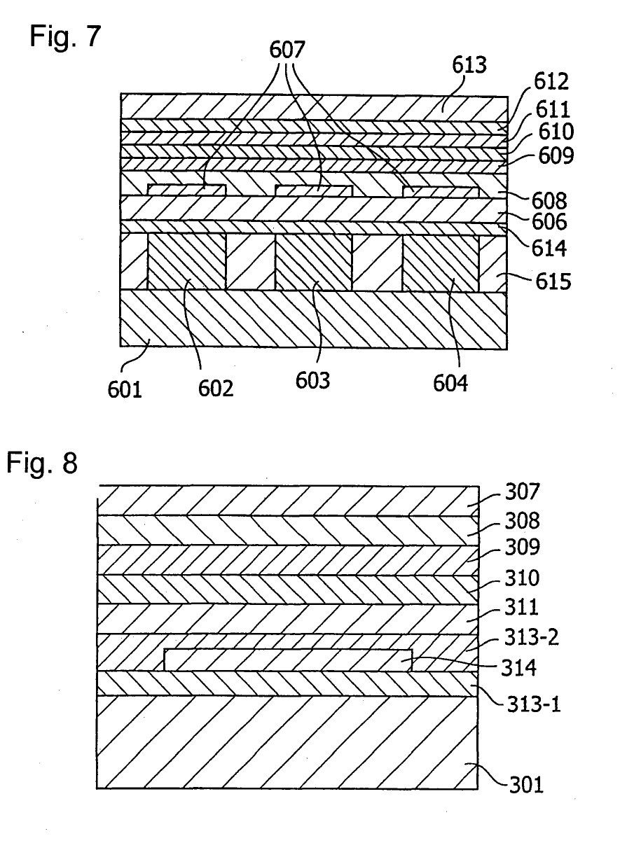

An organic EL display of Comparative Example 2 was produced in the same manner as in Example 1 except the points described in the following. FIG. 7 is a sectional view of an organic EL display of Comparative Example 2. The organic EL display of Comparative Example 2, as shown in FIG. 7, comprises transparent substrate 601, blue color filter layer 602, green color filter layer 603, red color filter layer 604, black matrix 615, color conversion layer 14, passivation layer 606, lower electrode (anode) 607, hole injection layer 608, hole transport layer 609, organic light emitting layer 610, an electron transport layer 611, electron injection layer 612, and upper electrode (cathode) 613. Upper electrode 613 was formed in the same manner as in Comparative Example 1.

In the organic EL display of Comparative Example 2, formed on transparent substrate 601 of corning 1737 glass by means of a photolithography method were: black matrix 615 (CK-7001, a product of Fuji Film Electronics Materials Co., Ltd.), red color filter layer 604 (CR-7001, a product of Fuji Film Electronics Materials Co., Ltd.), green color filter layer 603 (CG-7001, a product of Fuji Film Electronics Materials Co., Ltd.), and blue color filter layer 602 (CB-7001, a product of Fuji Film Electronics Materials Co., Ltd.). The thickness of these layers was 1 μm.

Color conversion layer 614 was formed as follows. A coating liquid was prepared by adding 0.05 g of coumarin 6 and 0.04 g of rhodamine B into 25 g of photoresist VPA100 (a product of Nippon Steel Chemical Co., Ltd.). Color conversion layer 614 having a thickness of 2 μm was formed by applying this coating liquid. Passivation layer 606 was formed of a SiOx film 0.5 μm thick by a sputtering method. Conditions except the thickness were the same as in the process of depositing the passivation layer in Example 1. The color conversion layer was formed at 180° C., which was lower by 30 to 70° C. than the temperature in Example 1.

### Example 3

### Top Emission Type; a Color Conversion Layer Between Lower Electrode Elements (Cathode)

FIG. 8 is a sectional view of the organic light emitting device of Example 3. The organic light emitting device of Example 3 is a top emission type device employing a color conversion scheme. The organic light emitting device of Example 3, as shown in FIG. 8, comprises transparent substrate 301, first lower electrode element (cathode) 313-1, color conversion layer 314, second lower electrode element (cathode) 313-2, electron transport layer 311, organic light emitting layer 310, hole transport layer 309, hole injection layer 308, and upper electrode (anode) 307.

First lower electrode element (cathode) 313-1 was formed on transparent substrate 301 as follows. An aluminum line pattern having a film thickness of 100 nm and a line width of 2 mm was formed as first lower electrode elements by means of a DC magnetron sputtering method using a mask.

Then, color conversion layer 314 was formed on first lower electrode elements (cathode) 313-1 without breaking the vacuum. The deposition of color conversion layer 314 was conducted by a mask evaporation method at a deposition speed of 0.1 nm/s. Material of the color conversion layer was 4-(dicyanomethylene)-2-methyl-6-(p-dimethylamino styryl)-4H-pyran (DCM). Thus, color conversion layer 314 having a thickness of 100 nm was deposited. The shape of the color conversion film was the same as in Example 1.

After that, second lower electrode elements (cathode) 313-2 were formed on color conversion layer 314 without breaking the vacuum. An Mg—Ag alloy film 30 nm thick was laminated by mask evaporation as transparent electrode 313-2.

Electron transport layer 311, organic light emitting layer 310, hole transport layer 309, and hole injection layer 308 were sequentially formed on the transparent electrode 313-2. Materials, thicknesses, deposition methods, and deposition conditions for these layers were the same as in Example 1.

Then, upper electrode (anode) 307 was formed on hole injection layer 308. An IZO film 200 nm thick was deposited for the upper electrode by a facing target sputtering method using a mask. The formed pattern of the upper electrode was a line pattern having a line width of 2 mm perpendicular to the lower electrode.

A sealing film (not shown in the figure) was formed as follows on upper electrode (anode) 307. The material used for the sealing film was SiN that is also used for a passivation film. Deposition of the sealing film was conducted by means of plasma CVD using SiH₄ gas (silane gas) and N₂ gas (nitrogen gas) in the flow rate of 15 sccm and 300 sccm, respectively, at the RF power of 15 W, the chamber temperature of 150° C., and the chamber pressure of 1.2 Torr. The sealing film had a thickness of 5 μm.

### Comparative Example 3

### Top Emission Type

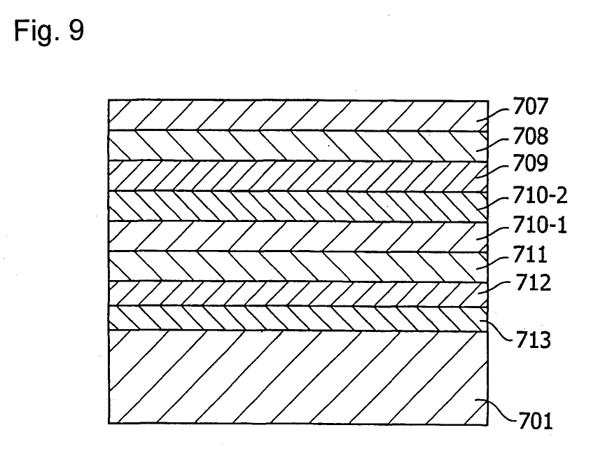

An organic light emitting device of Comparative Example 3 was produced in the same manner as in Example 3 except for the following changes. FIG. 9 is a sectional view of an organic light emitting device of Comparative Example 3. The organic light emitting device of Comparative Example 3 comprises, as shown in FIG. 9, transparent substrate 701, lower electrode (cathode) 713, electron injection layer 712, electron transport layer 711, red light emitting layer 710-1, blue light emitting layer 710-2, hole transport layer 709, hole injection layer 708, and upper electrode (anode) 707. Lower electrode 713 was the same as the second lower electrode element (cathode) in Example 3 except the thickness of 100 nm in lower electrode 713 of Comparative Example 3. The materials, the thicknesses, the deposition methods, and the deposition conditions of blue light emitting layer 710-1 and red light emitting layer 710-2 were the same as those in Comparative Example 1.

### Evaluation 1

### Evaluations of Brightness Retention Rate and Chromaticity Change

Evaluations of brightness retention rate and chromaticity change were carried out on the organic EL displays and organic light emitting devices of Examples 1, 2, and 3, and Comparative Examples 1 and 3. Three organic EL displays were produced for each of Example 1 and Comparative Example 1, and driven under the following conditions. As for Example 2, two organic EL displays were produced and driven under the same conditions. For each of Example 3 and Comparative Example 3, three organic light emitting devices were produced and driven under the same conditions.

Driving Conditions:

Linear sequential scanning: driving frequency 60 Hz, duty 1/60

Current density: 0.366 A/cm²

Evaluation of performances on these organic EL displays and the organic light emitting devices was carried out as follows. First, a voltage-current characteristics and current-brightness characteristics in dc condition were measured as the initial performance just after production, and after continuous driving for 1,000 hr, their retention rate was measured. Further, the change of CIE chromaticity coordinate due to the change of driving current density was measured just after production and after continuous driving for 1,000 hours, and variation of the x-value was compared. Table 1 shows brightness retention rate after continuous driving and the change of chromaticity due to the change of driving current density just after production and after continuous driving, for Examples 1, 2, and 3, and Comparative Examples 1 and 3. The brightness retention rate in the table is a retention rate (in %) of the brightness after continuous driving for 1,000 hours at the current density of 0.1 A/cm² with respect to the value just after production. The values of chromaticity change were obtained just after production and after continuous driving for 1,000 hours. To obtain each value of chromaticity change, driving current density was varied from 10^{-4 A/cm}² to 1 A/cm², and a value of chromaticity was calculated from the EL light emission spectrum at each driving current density. The difference between the maximum value and the minimum value of the chromaticity is the chromaticity change given in the table.

The performance evaluation was conducted using SourceMeter 2400 produced by Keithley Instruments, Inc. and a brightness meter BM-8 produced by Topcon Corporation. The EL spectrum was measured by an optical multi channel analyzer PMA-11 produced by Hamamatsu Photonics K.K.

As shown in Table 1, the change of CIE-x value was less than 0.005 (below accuracy of measurement) both just after production and after continuous driving for 1,000 hours in every Example according to the invention. It has been confirmed that the chromaticity change due to driving current density can be suppressed at the outset and after driving without degrading initial performance and brightness retention rate by using an organic light emitting device according to the invention. Therefore, the present invention provides a stable white light-emitting organic EL device and a full color organic EL display.

TABLE 1
Brightness retention rate after driving and change of CIE-x value at
initial and after driving

| | Brightness | Change of CIE-x | Change of CIE-x |
|---|---|---|---|
| | retention rate after | value | value |
| Sample | driving | initial | after driving |
| Example 1 | 88% | <0.005 | <0.005 |
| Example 2 | 91% | <0.005 | <0.005 |
| Example 3 | 89% | <0.005 | <0.005 |
| Comparative | 87% | 0.05 | 0.16 |
| Example 1 | | | |
| Comparative | 87% | 0.05 | 0.16 |
| Example 3 | | | |

### Evaluation 2

### Evaluation of DA Generation

Evaluation of dark area (DA) generation was conducted on the organic EL displays of Example 1 and Comparative Example 2. Each organic EL display was driven for 500 hours at a brightness of 100 cd/m² in a high temperature environment of 85° C. The sample was taken out after an every predetermined time and the pixels in the area having a fixed size were observed under a microscope, to inspect the change of DAs on the light emitting surface. The observation clearly showed that DAs larger than 50 μm were found at a density of 1 to 3 per cm² in the organic EL display of Comparative Example 2, while the DAs over 50 μm were very scarce in the organic EL display of Example 1.

Thus, an organic light emitting device has been described according to the present invention. Many modifications and variations may be made to the techniques and structures described and illustrated herein without departing from the spirit and scope of the invention. Accordingly, it should be understood that the methods and devices described herein are illustrative only and are not limiting upon the scope of the invention.

### DESCRIPTION OF SYMBOLS

1, 101, 201, 301, 501, 601, 701 substrate
7,107, 307, 507, 607, 707 lower electrode
7-1, 207-1 first lower electrode element
7-2, 207-2 second lower electrode element
8, 108, 208, 308, 508, 608, 708 hole injection layer
9, 109, 209, 309, 509, 609, 709 hole transport layer
10, 110, 210, 310, 510-1, 510-2, 610, 710-1, 710-2 light emitting layer
11, 111, 211, 311, 511, 611, 711 electron transport layer
12, 112, 212, 512, 612, 712 electron injection layer
13, 213, 513, 613, 713 upper electrode
13-1, 113-1, 313-1 first upper electrode element
13-2, 113-2, 313-2 second upper electrode element
14, 114, 214, 314, 614 color conversion layer
102, 202, 502, 602 blue color filter layer
103, 203, 503, 603 green color filter layer
104, 204, 504, 604 red color filter layer
105, 205, 505 planarizing layer
106, 206, 506, 606 passivation layer
615 black matrix

What is claimed is:

1. An organic light emitting device comprising:
a substrate;
a lower electrode disposed over the substrate;
an organic light emitting layer disposed over the lower electrode and in electrical contact with the lower electrode; and
an upper electrode disposed over the organic light emitting layer and in electrical contact with the organic light emitting layer;
wherein the upper electrode includes a first upper electrode element, a color conversion layer disposed on the first upper electrode element, and a second upper electrode element disposed on the color conversion layer and in electrical contact with the first upper electrode element.

2. An organic light emitting device comprising:
a substrate;
a lower electrode disposed over the substrate;
an organic light emitting layer disposed over the lower electrode and in electrical contact with the lower electrode; and
an upper electrode disposed over the organic light emitting layer and in electrical contact with the organic light emitting layer;
wherein the lower electrode includes a first lower electrode element, a color conversion layer disposed on the first lower electrode element, and a second lower electrode element disposed on the color conversion layer and in electrical contact with the first lower electrode element.

3. The organic light emitting device according to claim 1, wherein the first upper electrode element is transparent to visible light, the second upper electrode element is reflective to visible light, and the organic light emitting device is a bottom emission type.

4. The organic light emitting device according to claim 1, wherein the first upper electrode element and the second upper electrode element are transparent to visible light, and the organic light emitting device is a top emission type.

5. The organic light emitting device according to claim 2, wherein the first lower electrode element and the second lower electrode element are transparent to visible light, and the organic light emitting device is a bottom emission type.

6. The organic light emitting device according to claim 2, wherein the first lower electrode element is reflective to visible light, the second lower electrode element is transparent to visible light, and the organic light emitting device is a top emission type.

7. The organic light emitting device according to claim 3, wherein the transparent electrode element comprises an oxide of a metal selected from the group consisting of In, Sn, Zn, and Al, or a material selected from the group consisting of Al, an Al—Li alloy, Mg, and an Mg—Ag alloy.

8. The organic light emitting device according to claim 3, wherein the reflective electrode element is substantially composed of a metal selected from the group consisting of Al, Ag, Ni, Cr, Mo, and W.

9. The organic light emitting device according to claim 1, wherein the color conversion layer is formed by an evaporation method.

10. The organic light emitting device according to claim 1, wherein the color conversion layer exhibits absorbance of at least 1.0 at an absorption peak wavelength for light from the organic light emitting layer.

11. An organic EL panel for organic EL display displaying information by individually driving a plurality of pixels, wherein each of the pixels has a plurality of sub-pixels of different types, at least one type of the sub-pixels comprising the organic light emitting device according to claim 1, and a color adjustment layer disposed in an area substantially overlapping with the organic light emitting device.

12. The organic EL panel according to claim 11, wherein the upper electrode is striped, the lower electrode is striped, and the upper electrodes and the lower electrodes are disposed in a matrix configuration, and wherein the color conversion layer is circular and disposed in an area where the upper electrode and the lower electrode are overlapping, or the color conversion layer is rectangular and disposed in an area overlapping with the upper electrode or the lower electrode.

13. An organic EL display that comprises the organic light emitting device according to claim 1.

14. An organic EL display that comprises the organic EL panel defined by claim 11.

15. A method of producing an organic light emitting device comprising:
preparing a substrate;
providing a lower electrode over the substrate;
providing an organic light emitting layer disposed over the lower electrode and in electrical contact with the lower electrode; and
providing an upper electrode disposed over the organic light emitting layer and in electrical contact with the organic light emitting layer by providing a first upper electrode element, providing a color conversion layer on the first upper electrode element, and providing a second upper electrode element on the color conversion layer and in electrical contact with the first upper electrode element.

16. A method of producing an organic light emitting device comprising:
preparing a substrate;
providing a lower electrode over the substrate by providing a first lower electrode element, providing a color conversion layer on the first lower electrode element, and providing a second lower electrode element on the color conversion layer and in electrical contact with the first lower electrode element;
providing an organic light emitting layer disposed over the lower electrode and in electrical contact with the lower electrode; and
providing an upper electrode disposed over the organic light emitting layer and in electrical contact with the organic light emitting layer.

17. The organic light emitting device according to claim 4, wherein the transparent electrode element comprises an oxide of a metal selected from the group consisting of In, Sn, Zn, and Al, or a material selected from the group consisting of Al, an Al—Li alloy, Mg, and an Mg—Ag alloy.

18. The organic light emitting device according to claim 5, wherein the transparent electrode element comprises an oxide of a metal selected from the group consisting of In, Sn, Zn, and Al, or a material selected from the group consisting of Al, an Al—Li alloy, Mg, and an Mg—Ag alloy.

19. The organic light emitting device according to claim 6, wherein the transparent electrode element comprises an oxide of a metal selected from the group consisting of In, Sn, Zn, and Al, or a material selected from the group consisting of Al, an Al—Li alloy, Mg, and an Mg—Ag alloy.

20. The organic light emitting device according to claim 6, wherein the reflective electrode element is substantially composed of a metal selected from the group consisting of Al, Ag, Ni, Cr, Mo, and W.
